(19) United States
(12) Patent Application Publication
(10) Pub. No.: US 2013/0288070 A1
(43) Pub. Date: Oct. 31, 2013

(54) Method for Creating Asperities in Metal for Metal-to-Metal Bonding

(71) Applicant: ANALOG DEVICES, INC., Norwood, MA (US)

(72) Inventor: Christine H. Tsau, Arlington, MA (US)

(73) Assignee: ANALOG DEVICES, INC., Norwood, MA (US)

(21) Appl. No.: 13/783,491

(22) Filed: Mar. 4, 2013

Related U.S. Application Data
(60) Provisional application No. 61/639,155, filed on Apr. 27, 2012.

(51) Int. Cl. H05K 13/04

(52) U.S. Cl. CPC H05K 13/04
USPC 428/612; 228/164; 228/124.1

(57) ABSTRACT

A first metal such as germanium is prepared for metal-to-metal bonding by depositing the first metal onto a roughened foundation layer so that asperities are present on the first metal layer substantially following the topology of the asperities on the surface of the foundation layer without having to process the surface of the first metal layer. Such asperities can break through barrier layer(s) on the surface of another metal (e.g., an oxide layer, an anti-stiction coating, and/or other barrier layer) during a bonding process so that direct metal-to-metal bonding can be accomplished without having to remove the barrier layer(s) and without having to process the surface of the first metal such as by photolithography or depositing and subsequently removing a material that partially interdiffuses with the first metal.

### CROSS-REFERENCE TO RELATED APPLICATION(S)

This patent application claims the benefit of U.S. Provisional Patent Application No. 61/639,155 filed Apr. 27, 2012 (Attorney Docket No. 2550/D85), which is hereby incorporated herein by reference in its entirety.

### FIELD OF THE INVENTION

The present invention relates generally to metal-to-metal bonding, e.g., for MEMS fabrication, wafer-to-wafer bonding, wafer capping, wafer stacking, packaging, etc., and more specifically to creating asperities in a metal such as germanium for germanium-based bonding.

### BACKGROUND OF THE INVENTION

Metal eutectic bonding has a number of advantages over the prevailing frit glass bonding technique in capped MEMS sensor fabrication. The metal films can be patterned using standard fabrication techniques, leading to better dimensional control. The material choice can also be lead free, and with eutectic temperature within the CMOS thermal budget.

However, metal eutectic bonding is less forgiving of the wafer surface chemistry. Eutectic bonding relies on metals of interest to come into intimate contact and form the eutectic reaction at the appropriate temperature. The reaction can be impeded if there are oxides or other films present, thereby impeding successful wafer bonding. Unfortunately, oxide readily forms on most CMOS compatible metals (e.g., aluminum), and such oxides are difficult to remove chemically. In addition, many MEMS sensors have a thin anti-stiction coating (typically an organic coating, such as a self-assembled coating based on 1H,1H,2H,2H-perfluorodecyltrichlorosilane (FDTS)) on the surface to prevent stiction.

In some implementations, the anti-stiction coating can be preferentially removed from metal surfaces (although not as readily from silicon surfaces) using additional fabrication steps, and some anti-stiction coatings may thermally decompose from bonding surfaces during bonding. The anti-stiction coating can be difficult to remove chemically in released devices.

As metal oxide and anti-stiction coatings are often difficult to remove chemically (and typically are difficult to remove from a process perspective at the bonding phase of fabrication) and often do not thermally decompose in the temperature range typically used for bonding, one solution is to form asperities (i.e., protrusions or spikes) on the surface of a one of the bonding layers so that the asperities can penetrate through the oxide and/or coating (referred to generally herein as the “barrier layer”) to the underlying metal of the other bonding surface during bonding under temperature and pressure, enabling the eutectic reactions of the alloying metals to proceed. The barrier layer is estimated to be <100 A thick, so asperities on that order can allow the metal to mechanically break through the thin film barriers. The asperities should be random and small in size to maximize the pressure enhancement as the asperities punch through the barrier film(s).

For example, in a germanium-aluminum bonding process, the surface of the germanium layer may be roughened in order to create asperities that can penetrate the oxide and/or coating material on the surface of the aluminum. The surface of the germanium can be roughened in a number of ways. For example, the surface of the germanium can be roughened by photolithography, although this adds steps to the process flow, and a high resolution stepper needs to be employed. Alternatively, the surface of the germanium can be roughened by depositing a film over the germanium that has slight inter-diffusion with germanium (e.g., an aluminum film) and then stripping that film and the byproducts in order to leave a rough topology on the germanium surface.

Wafer-level bonding is discussed generally in US Publication No. 2012/0074590, which is hereby incorporated herein by reference in its entirety.

Germanium-aluminum bonding is discussed in U.S. Pat. No. 6,483,160, U.S. Pat. No. 7,981,765, U.S. Pat. No. 7,943,411, and US Publication No. 2012/0074417, each of which is hereby incorporated herein by reference in its entirety.

### SUMMARY OF EXEMPLARY EMBODIMENTS

In one embodiment there is provided a method for preparing a first metal (e.g., germanium) for bonding with a second metal having at least one barrier layer. The method involves forming asperities on a surface of a foundation layer and depositing the first metal onto the surface of the foundation layer such that the deposited first metal substantially follows the topology of the asperities on the surface of the foundation layer to form a first metal layer with asperities sufficient to penetrate through the at least one barrier layer on the second metal to the underlying second metal during a bonding process so that a metal-to-metal bond can be formed between the first metal and the second metal.

In another embodiment there is provided apparatus for metal-to-metal bonding, the apparatus including a foundation layer including asperities on a surface and a first metal (e.g., germanium) deposited onto the surface of the foundation layer such that the deposited first metal substantially follows the topology of the asperities on the surface of the foundation layer to form a first metal layer with asperities sufficient to penetrate through at least one barrier layer on a second metal to the underlying second metal during a bonding process so that a metal-to-metal bond can be formed between the first metal and the second metal.

In various alternative embodiments of such method and apparatus, the foundation layer may be a polysilicon foundation layer, in which case the asperities may be formed by doping the polysilicon foundation layer (e.g., with a POCl3 dopant) to form a doped polysilicon foundation layer and annealing the doped polysilicon foundation layer to form asperities. Asperities may be formed on other types of foundation layers and may be formed using other types of processes, such as, for example, depositing a material, etching a material, or patterning a material. In certain embodiments, a plurality of the asperities on the first metal layer may be at least around 100 A in height. The asperities formed on the surface of the foundation layer may be configured so that asperities of the first metal layer after deposition of the first metal will be sufficient to penetrate through the at least one barrier layer on the second metal to the underlying second metal (e.g., the height of the asperities on the surface of the foundation layer may be higher and/or lower than the desired asperities of the first metal layer such as to account for a particular process used to deposit the first metal).

Furthermore, the first metal layer with asperities may be bonded to the second metal under temperature and pressure such that a plurality of asperities of the first metal layer pierce through the at least one barrier layer to the underlying second metal to produce the metal-to-metal bond, i.e., without having to remove the barrier layer(s). The metal-to-metal bond may include a eutectic bond or a thermocompression bond. The barrier layer(s) may include an oxide of the metal and/or an anti-stiction coating on the metal.

Additional embodiments may be disclosed and claimed.

### BRIEF DESCRIPTION OF THE DRAWINGS

The foregoing and advantages of the invention will be appreciated more fully from the following further description thereof with reference to the accompanying drawings wherein:

FIG. 1 is a flow chart for a bonding process in accordance with an exemplary embodiment;

FIG. 2 is a flow chart for a bonding process in accordance with a specific embodiment in which the foundation layer is a polysilicon layer;

FIGS. 3-8 are schematic diagrams representing various fabrication steps discussed in FIG. 2, wherein:

FIG. 3 shows a substrate on which the polysilicon layer will be formed;

FIG. 4 shows the polysilicon formed on the substrate;

FIG. 5 shows the polysilicon layer after doping;

FIG. 6 shows the doped polysilicon layer after annealing;

FIG. 7 shows the sputtered germanium deposited onto the annealed polysilicon layer; and

FIG. 8 depicts bonding of the wafer with the germanium to another wafer with a metal layer having an oxide and/or other surface barrier layer;

FIG. 9 is a scanning electron microscope image of the asperities formed of germanium, specifically on a cap wafer; and

FIG. 10 is a scanning electron microscope image of indents formed by the germanium asperities in the facing metal on the sensor wafer after the two surfaces were placed into contact under pressure.

It should be noted that the foregoing figures and the elements depicted therein are not necessarily drawn to consistent scale or to any scale. Unless the context otherwise suggests, like elements are indicated by like numerals.

### DETAILED DESCRIPTION OF SPECIFIC EMBODIMENTS

In embodiments of the present invention, a metal such as germanium is prepared for bonding with another metal by depositing the germanium onto an already-roughened foundation layer so that asperities present on the foundation layer form corresponding asperities on the surface of the germanium layer without having to process the surface of the germanium layer.

Specifically, the foundation layer is roughened in order to produce asperities with characteristics appropriate for a particular implementation (i.e., size/height, shape, distribution of asperities). Generally speaking, the height of the asperities (or of a large proportion of the asperities) should be sufficient to penetrate through the expected thickness of the barrier layer(s) on the surface of the other metal to be bonded, which can include an oxide layer and/or other material layer (e.g., anti-stiction coating layer). The minimum effective height of the asperities may be different for different implementations, e.g., large asperities may be warranted when the other metal to be bonded includes both oxide and other barrier material, while smaller asperities may be acceptable when the other metal to be bonded has only oxide or only other material. For example, if the barrier layer is less than around 100 A thick, asperities of at least around 100 A in height may be sufficient to allow the metal to mechanically break through the barrier layer to the underlying metal. In some situations, smaller asperities may be sufficient (e.g., around 80 A) while in other situations, larger asperities may be needed.

After the asperities are formed on the foundation layer, the metal such as germanium is deposited using a deposition method in which the deposited metal substantially follows the topology of the underlying foundation layer, for example, by sputtering (other deposition techniques, such as deposition techniques based on chemical vapor deposition or atomic layer deposition may be used in some alternative embodiments). Generally speaking, a metal such as germanium deposited by sputtering tends to take on the topology of an underlying layer, so the asperities formed on the foundation layer form corresponding asperities on the surface of the germanium layer. Of course, due to natural variations in sputtering and certain other deposition techniques, the asperities formed on the surface of the deposited metal may be higher or lower than the asperities on the underlying substrate (or perhaps some may be higher and some may be lower), and implementations can take such variation into account. For example, if asperities of a minimum height are required on the surface of the metal, then, in some implementations, the asperities formed on the foundation layer may be slightly higher so as to better ensure that the asperities on the metal have sufficient height.

After the asperities have been formed on the metal layer, the metal layer may be bonded to another metal such that the asperities on the first metal layer penetrate through the barrier layer(s) on the other metal to the underlying base metal, allowing for a metal-to-metal bond to be formed. Generally speaking, such bonding is performed under temperature and pressure. The bond may be eutectic or may be made through other mechanism, such as, for example, thermocompression. Some exemplary germanium-based bonding is discussed in U.S. Pat. No. 6,483,160, U.S. Pat. No. 7,981,765, U.S. Pat. No. 7,943,411, and US Publication No. 2012/0074417, each of which is hereby incorporated herein by reference in its entirety.

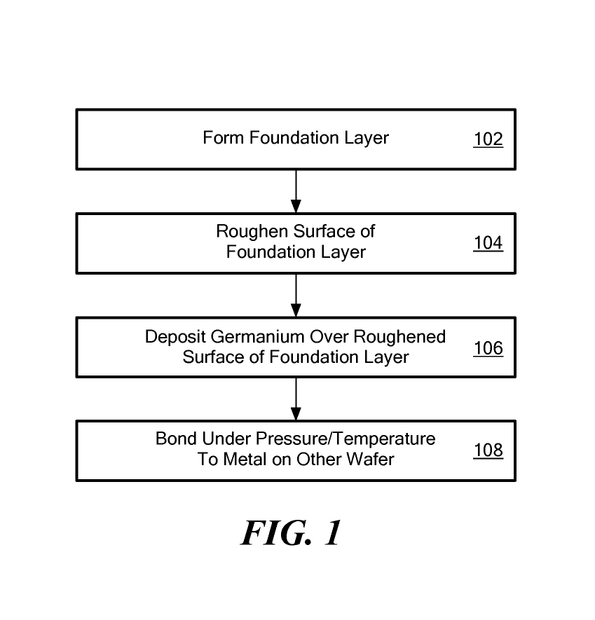

FIG. 1 is a flow chart for a bonding process in accordance with an exemplary embodiment.

In block 102, the foundation layer is formed. In some embodiments, this step is unnecessary, as the foundation layer may exist in a particular device (e.g., if the foundation layer is the wafer on which the remaining layer are formed, or if the foundation layer has been pre-formed such as in earlier fabrication steps). It should be noted that some foundation layers may be substantially smooth while other foundation layers may have bumps or other asperities, which may or may not be sufficient to produce the desired asperities on the germanium layer.

In block 104, the surface of the foundation layer is roughened (or further roughened, if the surface of the foundation layer is innately or previously roughened), e.g., by depositing asperities onto the surface, by etching asperities into the surface, by patterning asperities onto the surface, or by other asperity-forming technique such as depositing a reactive material onto the surface and later stripping the reactive material. In some embodiments, this “roughening” step may be unnecessary, e.g., if the foundation layer is sufficiently rough without the need for further roughening.

In block 106, a metal such as germanium is deposited over the roughened surface of the foundation layer, e.g., by sputtering or other appropriate deposition technique. Additional steps may be performed, such as patterning the metal.

In block 108, the metal with asperities is bonded to another metal on another device under temperature/pressure. The bond may be eutectic or may be made through other mechanism, such as, for example, thermocompression. Such bonding can be performed for any of a variety of reasons, such as wafer capping (e.g., where one wafer includes a MEMS device and/or electronic circuitry and the other wafer is a cap wafer), wafer stacking, flip-chip bonding (e.g., where one wafer may include a MEMS device and the other wafer may include electronic circuitry), device packaging, etc. Additional steps may be performed, such as patterning the metal and underlying polysilicon, e.g., to prevent diffusion of the metal (for example germanium) along the polysilicon grain boundaries. Any of a variety of post-bonding processes may be performed, such as, for example, adding a sealant over the bonding region or encapsulating the device to better ensure hermeticity.

In one specific embodiment, the foundation is polysilicon that inherently has some roughness. The polysilicon layer may be formed, for example, by forming an amorphous silicon layer (e.g., by depositing silicon at a temperature of around 540-580 degrees Celsius) and then annealing the amorphous silicon to form polysilicion, or the polysilicon layer may be formed directly by depositing silicon at a temperature above around 600 degrees Celsius. The surface of the polysilicon is further roughened by first doping the polysilicon (e.g., P-doping using Phosphoryl Chloride or POCl3) and then annealing the doped polysilicon. Such processing of the polysilicon increases the asperities on the surface of the polysilicon. Then, a metal such as germanium is deposited (e.g., by sputtering) and patterned. As mentioned above, sputtered metal such as germanium takes on the topology of the underlying layer, so the asperities formed on the polysilicon layer form corresponding asperities on the surface of the metal layer. Then, polysilicon seed layers that surround the metal are typically removed to prevent surface diffusion along grain boundaries at the bonding temperature. The metal with asperities can then be bonded to another metal (e.g., aluminum) under temperature/pressure.

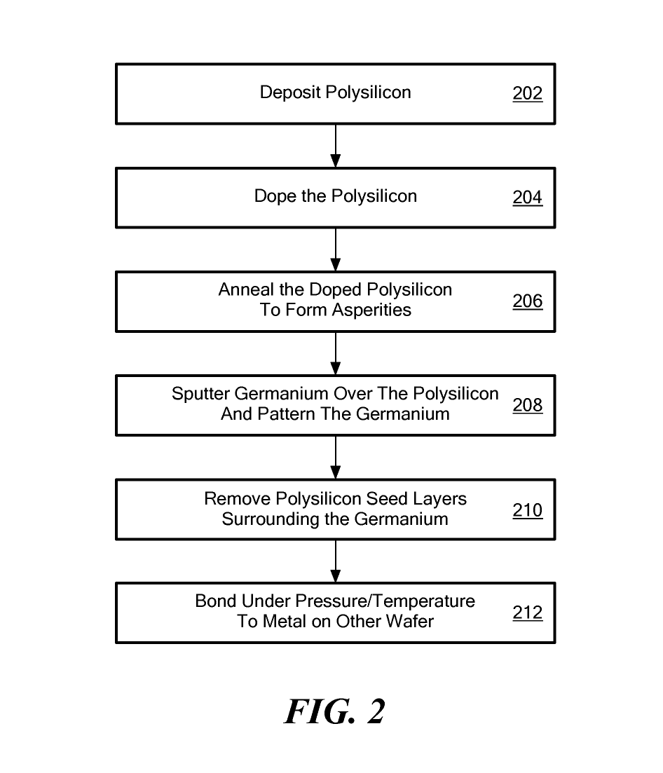

FIG. 2 is a flow chart for a germanium-based bonding process in accordance with this specific embodiment. In block 202, a polysilicon layer is deposited or otherwise formed. In block 204, the polysilicon is doped. In block 206, the doped polysilicon is annealed to further roughen the surface. In block 208, germanium is deposited over the roughened surface of the polysilicon layer by sputtering. In block 210, polysilicon seed layer surrounding the germanium is removed so as to eliminate surface diffusion paths. In block 212, the germanium is bonded to a metal on another wafer under temperature/pressure.

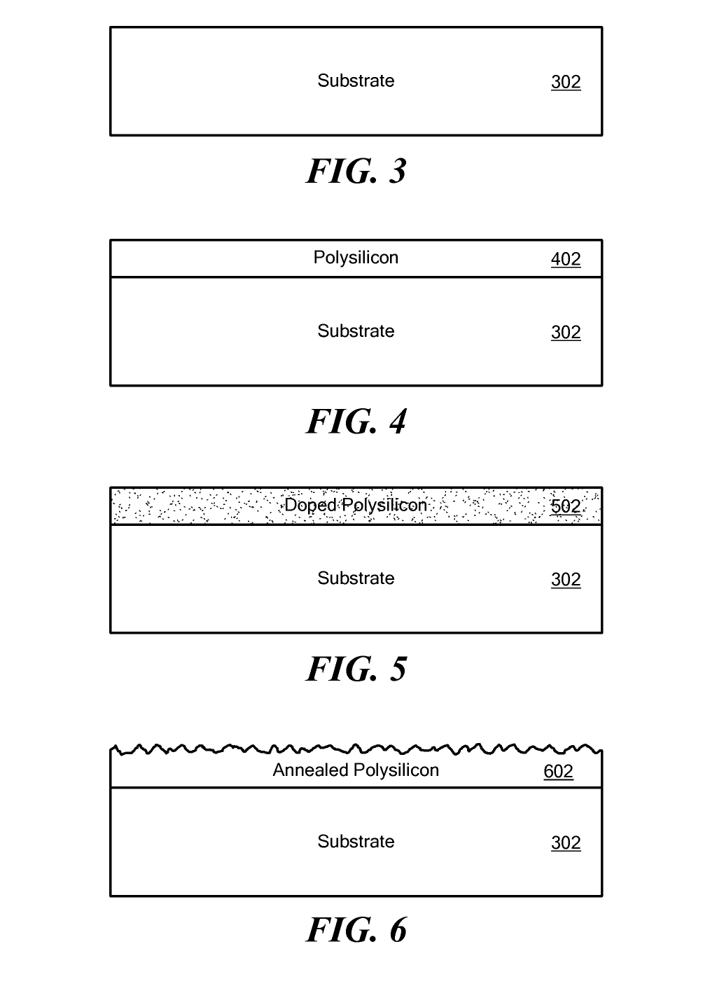

The fabrication steps described with reference to FIG. 2 are depicted schematically in FIGS. 3-8.

FIG. 3 shows a substrate 302 on which the polysilicon layer will be formed. The substrate can be virtually any material, such as a silicon wafer, a silicon-on-insulator wafer (or a layer of a silicon-on-insulator wafer), or a layer of material formed on a wafer.

FIG. 4 shows the polysilicon foundation layer 402 formed on the substrate 302. This can be done, for example, by depositing and patterning a silicon or polysilicon material. The surface of the polysilicon layer is shown as being substantially flat, although it should be noted that the surface typically has bumps or other asperities.

FIG. 5 shows the polysilicon layer 502 after doping (with the dopant represented by the specks in the polysilicon material).

FIG. 6 shows the doped polysilicon layer 602 after annealing, including the asperities formed or enhanced thereby.

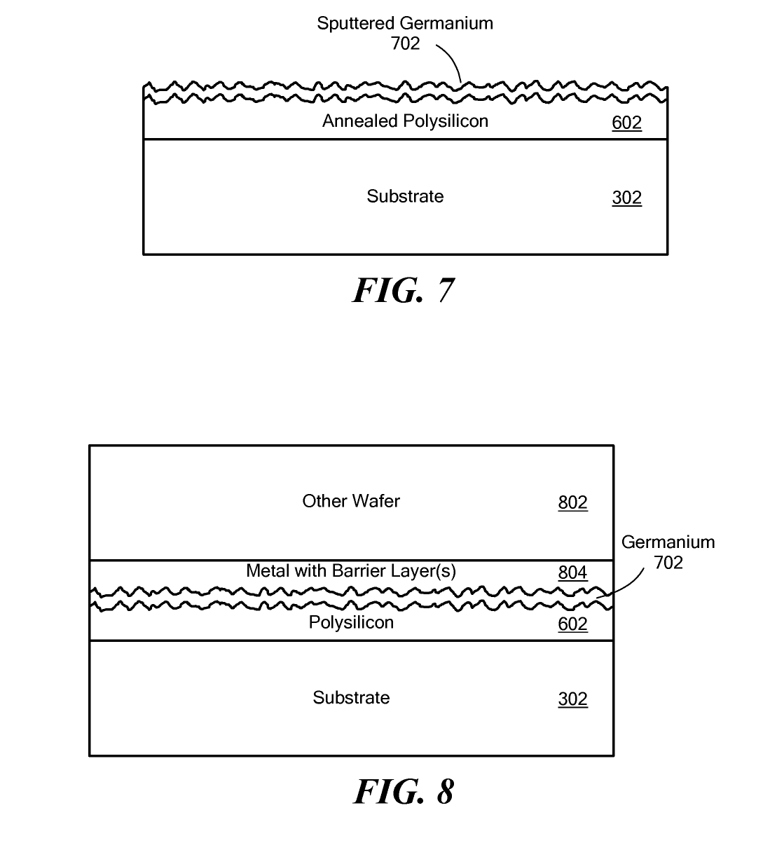

FIG. 7 shows the sputtered germanium 702 deposited onto the annealed polysilicon layer 602 such that the asperities on the polysilicon foundation layer 602 form asperities on the surface of the germanium layer 702.

FIG. 8 depicts bonding of the substrate with the germanium to another substrate 802 with a metal layer having an oxide and/or other surface barrier layer 804. Typically, the two metal layers to be bonded are brought into contact under pressure and temperature. As discussed above, the asperities on the surface of the germanium layer penetrate through the barrier layer(s) on the other metal to allow for metal-to-metal bonding.

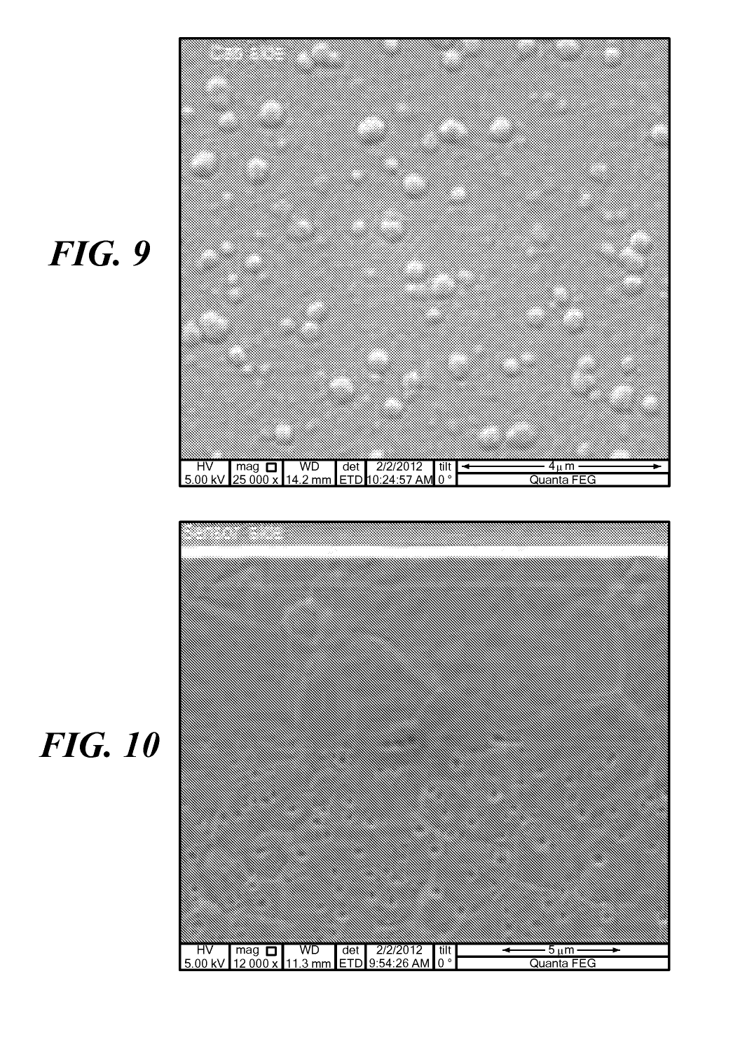

FIG. 9 is a scanning electron microscope image of the asperities formed of germanium, specifically on a cap wafer.

FIG. 10 is a scanning electron microscope image of indents formed by the germanium asperities in the facing metal on the sensor wafer after the two surfaces were placed into contact under pressure.

It should be noted that the exemplary processes discussed above may involve metals other than germanium and may include (and often do include) additional and/or alternate steps that are omitted for convenience. For example, an intermediate material may be included between the foundation layer and the metal layer, patterning may include various deposition and etching steps, etc.

Thus, embodiments include devices having a foundation layer including asperities on a surface and also having a sputtered germanium layer over such surface of the foundation layer, the sputtered germanium layer including asperities, wherein the asperities on the germanium layer substantially follow the topology of the asperities on the surface of the foundation layer. With respect to bonding of wafer devices, such devices are essentially intermediate devices prepared for bonding of the germanium with another metal on another wafer.

Embodiments also include bonded devices in which the foundation layer and the metal layer with asperities are on a first substrate and the other metal is on a second substrate, with the metal layer with asperities bonded to the other metal such that the asperities pierce through the surface barrier layer of the other metal to underlying metal to produce a metal-to-metal bond.

The present invention may be embodied in other specific forms without departing from the true scope of the invention, and numerous variations and modifications will be apparent to those skilled in the art based on the teachings herein. Any references to the “invention” are intended to refer to exemplary embodiments of the invention and should not be construed to refer to all embodiments of the invention unless the context otherwise requires. The described embodiments are to be considered in all respects only as illustrative and not restrictive.

What is claimed is:

1. A method for preparing a first metal for bonding with a second metal having at least one barrier layer, the method comprising:
forming asperities on a surface of a foundation layer; and
depositing the first metal onto the surface of the foundation layer such that the deposited first metal substantially follows the topology of the asperities on the surface of the foundation layer to form a first metal layer with asperities sufficient to penetrate through the at least one barrier layer on the second metal to the underlying second metal during a bonding process so that a metal-to-metal bond can be formed between the first metal and the second metal.

2. A method according to claim 1, wherein the foundation layer is a polysilicon foundation layer.

3. A method according to claim 2, wherein forming asperities on the surface of the foundation layer comprises:
doping the polysilicon foundation layer to form a doped polysilicon foundation layer; and
annealing the doped polysilicon foundation layer to form asperities.

4. A method according to claim 3, where doping the polysilicion foundation layer comprises doping the polysilicon foundation layer with a POCl3 dopant.

5. A method according to claim 1, wherein forming asperities on the surface of the foundation layer comprises at least one of depositing a material, etching a material, or patterning a material.

6. A method according to claim 1, wherein a plurality of the asperities on the first metal layer are at least around 100 A in height.

7. A method according to claim 1, wherein the asperities formed on the surface of the foundation layer are configured so that asperities of the first metal layer after deposition of the first metal will be sufficient to penetrate through the at least one barrier layer on the second metal to the underlying second metal.

8. A method according to claim 1, further comprising:
bonding the first metal layer with asperities to the second metal under temperature and pressure such that a plurality of asperities of the first metal layer pierce through the at least one barrier layer to the underlying second metal to produce the metal-to-metal bond.

9. A method according to claim 8, wherein at least one of
the metal-to-metal bond includes a eutectic bond;
the metal-to-metal bond includes a thermocompression bond;
the at least one surface barrier layer includes an oxide of the metal; or
the at least one surface barrier layer includes an anti-stiction coating on the metal.

10. A method according to claim 1, wherein the first metal comprises germanium.

11. Apparatus for metal-to-metal bonding, the apparatus comprising:
a foundation layer including asperities on a surface; and
a first metal deposited onto the surface of the foundation layer such that the deposited first metal substantially follows the topology of the asperities on the surface of the foundation layer to form a first metal layer with asperities sufficient to penetrate through at least one barrier layer on a second metal to the underlying second metal during a bonding process so that a metal-to-metal bond can be formed between the first metal and the second metal.

12. Apparatus according to claim 11, wherein the foundation layer is a polysilicon foundation layer.

13. Apparatus according to claim 12, wherein the polysilicon layer with asperities is a doped and annealed polysilicon layer.

14. Apparatus according to claim 13, where the polysilicon layer is doped with a POCl3 dopant.

15. Apparatus according to claim 11, wherein the foundation layer with asperities is one of
a foundation layer with asperities deposited on the surface;
a foundation layer with asperities etched into the surface; or
a foundation layer with asperities patterned onto the surface.

16. Apparatus according to claim 11, wherein a plurality of the asperities on the first metal layer are at least around 100 A in height.

17. Apparatus according to claim 11, wherein the asperities formed on the surface of the foundation layer are configured so that asperities of the first metal layer after deposition of the first metal will be sufficient to penetrate through the at least one barrier layer on the second metal to the underlying second metal.

18. Apparatus according to claim 11, wherein the foundation layer and the first metal layer with asperities are on a first substrate, and wherein the apparatus further comprises a second substrate including the second metal and at least one surface barrier layer on the second metal, the first metal layer bonded to the second metal such that a plurality of asperities of the first metal layer pierce through the at least one surface barrier layer to the underlying second metal to produce the metal-to-metal bond.

19. Apparatus according to claim 18, wherein at least one of
the metal-to-metal bond includes a eutectic bond;
the metal-to-metal bond includes a thermocompression bond;
the surface barrier layer includes an oxide of the metal; or
the surface barrier layer includes an anti-stiction coating on the metal.

20. Apparatus according to claim 11, wherein the first metal layer comprises germanium.
